(19) United States
(12) Patent Application Publication
(10) Pub. No.: US 2025/0171624 A1
(43) Pub. Date: May 29, 2025

(54) CONNECTION COMPONENT FOR AN ELECTRICAL CONDUCTOR

(71) Applicant: Phoenix Contact GmbH & Co. KG, Blomberg (DE)

(72) Inventors: Mike ADAMIK, Paderborn (DE); Manuel TÜNKER, Dörentrup (DE)

(21) Appl. No.: 18/951,698

(22) Filed: Nov. 19, 2024

(30) Foreign Application Priority Data
Nov. 28, 2023 (DE) DE102023133227.9

(51) Int. Cl. C08L 23/06; C08J 7/04; C08L 61/00; C08L 67/02; C08L 69/00; C08L 71/00; C08L 77/00; C08L 81/02; C08L 83/04; H05K 5/02

(52) U.S. Cl. CPC C08L 23/06; C08J 7/0427; C08L 61/00; C08L 67/02; C08L 69/00; C08L 71/00; C08L 77/00; C08L 81/02; C08L 83/04; H05K 5/0209; C08L 2201/02; C08L 2201/06; C08L 2312/00

(57) ABSTRACT

A connection component for an electrical conductor includes: at least one component body formed, at least in portions, by a plastics material. The plastics material includes a flame retardant. The plastics material is free of perfluorinated or polyfluorinated alkyl compounds. The flame retardant includes a polymer structure of the plastics material and/or an additive incorporated in the polymer structure of the plastics material that substitutes for the perfluorinated or polyfluorinated alkyl compounds, and/or an outer layer formed on the component body.

### CROSS-REFERENCE TO PRIOR APPLICATION

Priority is claimed to German Patent Application No. DE 10 2023 133 227.9, filed on Nov. 28, 2023, the entire disclosure of which is hereby incorporated by reference herein.

### FIELD

The invention relates to a connection component for an electrical conductor, which has at least one component body which is formed at least in portions from a plastics material, wherein the plastics material has a flame retardant.

### BACKGROUND

Connection components are used in particular for separating and connecting electrical conductors or cables. One requirement for connection components is that in particular the component body, which is made at least in portions from a plastics material, must not be combustible or flammable or only in particular cases. In manufacturing processes, which also comprise logistical and testing process stages, it is therefore important to avoid any fire hazard from the component bodies if they are exposed to flames, heat or other influences that could cause or spread a fire. In the case of connection components, the plastics material of the component body therefore contains a flame retardant in order to reduce or prevent dangerous fire behavior of the connection component. The plastics material used in connection components often comprises polycarbonate (PC), polyamide (PA), polyketones (PK) or polybutylene terephthalate (PBT), but can also comprise so-called polymer blends, i.e., mixtures such as polycarbonate (PC) with acrylonitrile-butadiene-styrene copolymer (ABS) or polycarbonate (PC) with polyethylene terephthalate (PET) or polycarbonate (PC) with polybutylene terephthalate (PBT), since these plastics materials have high strength and rigidity.

Flame retardants are characterized by the fact that they make it more difficult for a material to ignite, or prevent or at least delay the spread of flames. Such substances are also known as flame retardants.

Additives are known from the prior art that are introduced into the plastics material in order to modify the fire behavior in the event of flames and/or thermal influence, in accordance with the requirements. Per-and polyfluorinated alkyl compounds, also known by the acronym PFAS, have become common for this purpose. In the following, the aforementioned alkyl compounds are also referred to by the acronym PFAS.

PFAS are characterized, among other things, by high thermal and chemical stability, which has an advantageous effect on plastics materials with the corresponding properties.

However, the problem with these compounds is that they degrade slowly, and therefore cause an ecological burden when disposed of. Furthermore, these compounds are considered harmful to health-causing cancer, among other things.

### SUMMARY

In an embodiment, the present invention provides a connection component for an electrical conductor, comprising: at least one component body comprising, at least in portions, a plastics material, wherein the plastics material comprises a flame retardant, wherein the plastics material is free of perfluorinated or polyfluorinated alkyl compounds, and wherein the flame retardant comprises a polymer structure of the plastics material and/or an additive incorporated in the polymer structure of the plastics material that substitutes for the perfluorinated or polyfluorinated alkyl compounds, and/or an outer layer formed on the component body.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIGS. 1A to 1C are a schematic illustration of a component body of a connection component according to the invention, wherein the housing part designed as a sleeve housing is formed from multiple components,

FIG. 2 is a schematic illustration of a component body of a connection component according to the invention, wherein the component body is a frame part in the form of a holding frame,

FIGS. 3A to 3D are multiple schematic illustrations of a modular contact insert;

FIGS. 4A and 4B are two different schematic illustrations of a fixed-pole contact insert,

FIGS. 5A and 5B are a schematic illustration of a cable feedthrough frame and an insert that can be used in the cable feedthrough frame as a cable receiving part.

### DETAILED DESCRIPTION

In an embodiment, the present invention provides a connection component with a fire-retardant behavior which at least reduces or prevents at least one of the aforementioned limitations.

The connection component according to the invention is wherein the plastics material is free of perfluorinated or polyfluorinated alkyl compounds (PFAS) and the flame retardant is formed by a polymer structure of the plastics material and/or by an additive which is incorporated in the polymer structure of the plastics material and which substitutes for the perfluorinated or polyfluorinated alkyl compounds (PFAS), and/or by an outer layer formed on the component body.

The invention departs from the idea of providing additional environmental measures to protect a connection component from flames or thermal as well as chemical influences. At the same time, the invention breaks away from the idea of producing the component body from a metal instead of a plastics material. Furthermore, the invention moves away from the approach of providing special disposal means to achieve flame retardancy. The invention further refines the connection component itself.

The invention thus substitutes per-and polyfluorinated alkyl compounds (PFAS) by an intrinsic design and arrangement of the component body for flame retardancy and thus avoids a complex adaptation of the environment.

For this purpose, the invention provides a polymer structure of the plastics material which is configured and designed in such a way that resistance to flames can be achieved by the construction of the polymer structure.

The invention achieves an intrinsic flame retardant effect through the plastics material instead of or in addition to the construction of the polymer structure by incorporating an additive that is at least neutral for health concerns into the PFAS-free plastics material. For this purpose, the invention provides a PFAS-substituting additive which is incorporated into the polymer structure. According to the invention, a PFAS-substituting additive is an additive which, in particular, equivalently substitutes the fire or flame-retardant effect of the PFAS in the plastics material in question (base material)-at least essentially. Accordingly, within the meaning of the invention, the additive is an additive in the base material or the plastics material that is equivalent to PFAS with regard to the desired or required properties.

Furthermore, the invention proposes an intrinsic flame retardant effect of the component body in that the flame retardant is formed by an outer layer of the component body. According to the invention, this outer layer ensures that the component body is temporarily protected from thermal destruction at least within a required framework, without thereby or only to a tolerable extent reducing the properties of the component body.

The plastics material and/or the polymer structure of the plastics material can be configured and designed such that heating above a melting temperature of the plastics material can cause flame-free melting of the plastics material. This makes it possible to minimize the measures necessary to achieve sufficient flame retardancy, such that the desired properties do not have to be adapted by further means, and the flame retardancy can be achieved intrinsically by the plastics material. This means that effective flame retardancy can be achieved with little effort. A component body designed in this way can ensure that the occurrence or further spread of a fire can be prevented even if the shape of the component body is destroyed or disintegrates under the influence of flames or thermal influences. This ensures that the component body does not constitute a source of danger for fire or for the spread of fire. A fire hazard exists in particular if the shape of a component body disintegrates and fragments thereof separate. These fragments can contribute to the spread of a fire.

To prevent this, the plastics material and/or the polymer structure of the plastics material can be designed such that flame-free droplet formation of the plastics material can be achieved at a heating temperature at or above a melting temperature of the plastics material, such that the plastics material melts, forming droplets. This means that further precautionary measures, such as shielding elements or reinforcements of structures surrounding the component body, are unnecessary. Furthermore, this can ensure that even under extreme conditions, the formation of open flames and the spread of fire through the component body itself can be effectively prevented.

A further advantageous development of the invention relates to the additive for forming a flame retardant. According to the invention, a flame retardant effect can be achieved by the additive itself or in combination with other components and additives.

For example, it is possible that the additive can be incorporated in a soluble form into the plastics material. A soluble uptake of an additive contributes to the additive being distributed in the plastics material, preferably homogeneously. However, it is necessary that the composition of the plastics material allows this.

Furthermore, it is possible, for example, that the additive can be incorporated in an insoluble manner in the plastics material. The additive can then be a filler or at least contain a filler. This has the advantage that the introduction of such an additive into the plastics material is simplified. Furthermore, in this way it is possible to distribute the additive in a targeted and concentrated manner at different locations in the plastics material in order, for example, to form different zones with corresponding material properties. Furthermore, this makes it possible to optimally design the material properties of the plastics material for a connection component according to the invention in accordance with the requirements.

The additive can be an organic substance, such as, for example and in particular, an antimony or an antimony trioxide, which, when mixed into the plastics material of a component body according to the invention, can achieve a flame retardant effect.

Irrespective of this, within the scope of the invention the plastics material can be an organic as well as an inorganic plastics material.

Accordingly, it is possible according to the invention to inexpensively form a flame retardant using aluminum.

However, within the scope of the invention, it has also been shown to be advantageous that the additive is an inorganic substance or comprises an inorganic substance. This makes it possible to adapt the flame retardant to the other components of the plastics material in a wide range of embodiments and to use interactions between the components accordingly.

Inorganic substances are able to increase the melting temperature of a component body according to the invention and have the advantage that they do not form carbon dioxide. Furthermore, they can be produced inexpensively and are therefore cost-effective to use.

In the scope of the invention, a substance is in particular a chemical substance which can be formed from an element, a compound or a mixture. A substance can be formed from or consist of one molecule, multiple molecules, a molecular chain, an element, or an ionic compound. Here, the invention also comprises any combination of the aforementioned embodiments.

Within the scope of the invention, it has proven advantageous that the inorganic substance can comprise or be formed from a phosphorus substance and/or a nitrogen substance and/or a bromine substance.

A phosphorus substance in the scope of the invention contains at least phosphorus. For example, and in particular, so-called black phosphorus proves to be flame-retardant as well as inert and, moreover, non-toxic, so that a connection component according to the invention benefits from these properties when using such a substance. The invention thus allows for the formation or use of an organophosphorus or organic phosphorus-based flame retardant in a connection component according to the invention, which can additionally comprise in particular other substances. Organophosphorus flame retardants according to the invention consist of or comprise, for example and in particular, tris(chloropropyl) phosphate, halogen-free organophosphates, such as, for example and in particular, triphenyl cresyl phosphate. In the plastics material, these can be added individually or in any combination, for example and in particular as so-called plasticizers.

A nitrogen substance in the scope of the invention contains at least nitrogen. Nitrogen is non-flammable, so that a connection component according to the invention can be designed with the effect of nitrogen.

Within the scope of the invention, the flame retardant can, for example and in particular, be designed as a halogen-organic flame retardant or have such a substance, wherein, for example, a design as a bromine-containing flame retardant has proven to be particularly inexpensive and advantageous. Halogen-organic flame retardants in particular have a high chemical stability, which means that flame retardancy can be correspondingly stable.

In the scope of the invention, a bromine substance is a substance formed by or using bromine. A connection component according to the invention comprises, for example and in particular, a brominated flame retardant, wherein it can be designed to be flame-retardant. Thus, according to the invention, a brominated flame retardant consists, for example and in particular, of or is formed from a polybrominated diphenyl ether.

In addition to hexabromocyclododecane, tetrabromobisphenol A and polybrominated biphenyls have also proven to be suitable as optional substances within the scope of the invention.

Preferably, it can further be provided that the plastics material and/or the polymer structure of the plastics material is formed from at least one of the following polymers or comprises such a copolymer:
polyetherketone (PEEK for short),
high-temperature-resistant plastics material, in particular polyphenylene sulfide (for short PPS),
synthetic polymer, in particular silicones,
polyethylene (PE for short), in particular high molecular weight polyethylene (PE-UHMW for short)
polycarbonate (PC),
polyamide (PA),
polyketones (PK)
polybutylene terephthalate (PBT)
polymer blends such as polycarbonate (PC) with acrylonitrile-butadiene-styrene copolymer (ABS) or polycarbonate (PC) with polyethylene terephthalate (PET) or polycarbonate (PC) with polybutylene terephthalate (PBT).

Polyetherketone is characterized by the fact that it is a high-temperature-resistant plastics material that can contribute to a high level of flame retardancy.

Polyethylene is a proven thermoplastic that can be easily adapted to a variety of requirements. Polyethylene is, among other things, thermally deformable and suitable for welding, so that this material offers a high degree of design and forming possibilities. Polyethylene also has good chemical resistance. Polyethylene has the property that its molecular weight can be significantly increased by polymerization, which also increases its wear resistance and impact strength accordingly. This makes it possible to produce high molecular weight or ultra-high molecular weight polyethylene with the appropriate molecular weight, which means that the aforementioned properties can be adapted accordingly. This can be achieved, among other things, by replacing carbon-hydrogen bonds (for short: C—H bonds) and carbon-carbon bonds (for short: C—C bonds) by bonds between carbon and so-called heteroatoms, e.g., fluorine, nitrogen and also oxygen as well as more stable aromatic bonds. This means that it can be adapted for a wide range of applications of a connection component according to the invention. For example, and in particular, the heat resistance can be adjusted by increasing the enthalpy of fusion and reducing the entropy of fusion, thereby making the resistance to high temperatures adjustable.

In the scope of the invention, high-temperature-resistant plastics materials are those plastics materials or polymers that have a high resistance to thermal influences. Furthermore, these plastics materials exhibit very good mechanical properties, so that they remain dimensionally stable even under high thermal influences. Furthermore, they have a high melting point and high tensile strength and rigidity. According to the invention, these include polyphthalamides (for short PPA), which can be reinforced by means of glass fibers incorporated into them and have a high mechanical strength as well as thermal resistance. They have a high heat resistance of over 280° C. They also show low moisture absorption, which can be in the range of 0.1-0.3% by mass. This means that their physical properties remain essentially unaffected at least by moisture.

In this context, the invention proposes in particular polyphenylene sulfide as a predestined high-temperature-resistant plastics material. Polyphenylene sulfide is characterized by very high chemical and heat resistance as well as rigidity. Polyphenylene sulfide is very easy to injection mold, so that even thin walls can be produced with it. This makes this material also suitable for the realization of filigree shapes. Polyphenylene sulfide can also be easily combined with other materials, so that glass, carbon and aramid fibers can also be embedded therein.

The invention further proposes the use of a synthetic polymer; in particular, silicones, which are also referred to as polysiloxanes or polyorganosiloxanes, are suitable for forming a connection component according to the invention. Synthetic polymers can be produced inexpensively on an industrial scale and can be easily adapted to the requirements placed on a connection component according to the invention.

Silicones have advantageous properties, which include good chemical resistance to many chemicals as well as high temperature resistance and elasticity at both high and low temperatures. Furthermore, silicones exhibit a resistance to UV rays and ozone. Furthermore, other materials such as glass fiber can be embedded in silicones in order to design a plastic or a plastics material with the desired characteristics.

Polycarbonate is an engineering thermoplastic characterized by high transparency, high heat resistance and good impact strength.

Polyamide is a material with high strength and rigidity, excellent impact strength and good abrasion and wear resistance. Polyamides can be easily treated with flame retardants and can withstand short-term temperatures of up to 260° C., such as those that can occur when soldering components, without substantial deformation.

A polyketone (PK) plastics material is a tough, semi-crystalline thermoplastic that has an alternating structure of carbon monoxide and ethylene or propene. The use of carbon monoxide as a monomer results in a plastics material with a particularly advantageous CO2 balance. The molecular structure of the PK polymer allows for a high degree of crystallization. PK material therefore has exceptionally high toughness, good wear resistance and very good chemical resistance.

Polybutylene terephthalate is valued for its high strength and rigidity, very high dimensional stability and good friction and wear properties.

Thus, a connection component according to the invention can benefit from the properties of the aforementioned polymers or copolymers or polymer blends, which can also be used in any combination with one another for a connection component according to the invention or its component body, and which can form it accordingly.

The plastics material and/or the polymer structure of the plastics material can have an organic and/or inorganic compound structure at least in portions. The invention thus opens up the possibility of being able to adapt a corresponding component body very flexibly. The invention takes into account, for example and in particular, that the polymer structure can be constructed in the manner of a salt. For example and in particular, at least five highly effective organic compounds can be added to the polymer structure. Within the scope of the invention, for example and in particular, a proportion of up to 25 percent by weight of these aforementioned compounds is possible. Furthermore, for example and in particular to such an extent, metal oxides can be added to a plastics material made of polypropylene.

The inorganic compound structure may contain or be formed from phosphorus and/or nitrogen. Nitrogen has the property that it can take on a crystalline form and is therefore also available as polymeric nitrogen. According to the invention, nitrogen can be used to improve a component body according to the invention with regard to the resistance and strength of the polymer and, in particular, to prevent undesirable discoloration or oxidation processes. The advantageous use of phosphorus for forming a component body according to the invention has already been described previously, so that reference is made to the features described there, which apply analogously here.

The plastics material and/or the polymer structure of the plastics material can be configured and designed such that the flame retardant is formed by a crosslinking modification by means of irradiation, in particular by means of gamma and/or beta irradiation, preferably X-ray irradiation. The formation of a flame retardant can be achieved by changing the polymer structure, which can make additional additives, fillers, material combinations as well as reinforcements, such as materials embedded in the polymer, unnecessary. This makes it possible to form a flame retardant at a late stage in the production of a component body according to the invention, and to achieve this in a targeted and inexpensive manner.

Within the scope of the invention, it has been shown that plastics parts exhibit improved properties after irradiation, which can be demonstrated by heat resistance, improved creep behavior, and also higher abrasion resistance. By means of irradiation, it is possible to improve a component body with regard to its mechanical, thermal and chemical properties. This makes it possible to improve the properties of a plastic or a plastics material in an inexpensive manner by means of irradiation in order to at least meet the required properties.

To form a flame retardant, the invention provides a further option of achieving a structural modification by means of irradiation. For this purpose, X-rays have proven particularly suitable within the scope of the invention, as they can be produced inexpensively and the duration of the influence of the X-rays on the plastics material determines the type and extent of the formation of the flame retardant via a modification of the polymer structure. It has been shown that irradiation can be used to change and improve the properties of a wide range of plastics and plastics materials. For example and in particular, thermoplastics, thermoplastic elastomers and elastomers can be adapted by means of irradiation. To achieve the desired properties, the plastics material can be irradiated with a predetermined intensity and duration. This depends on the type and extent of the desired change in the properties of the plastics material. The plastics material absorbs the radiation energy, releasing free radicals that can form a polymer structure with the desired properties in a molecular compound. Thus, within the scope of the invention, it is possible to form the flame retardant by targeted irradiation in portions, partially, or in layers. This provides the advantage of being able to form different regions according to the requirements. The invention thus allows for individual adaptation of a component body. Furthermore, this advantageously makes it possible to achieve the property adaptation in a late production phase and, in particular, to carry out irradiation after the shaping of a component body.

For this purpose, a corresponding advantageous development of the invention provides that the polymer structure of the plastics material is configured and designed such that the flame retardant is formed by a crosslinking modification by means of irradiation, in particular by means of gamma or beta irradiation, preferably X-ray irradiation. The invention thus makes it possible, for example and in particular, for polymer chains to crosslink with one another and thereby change the characteristics of a thermoplastic towards the characteristics of a thermoset. This effectively prevents melting or dissolving of the structural composite of the plastics material even at high temperatures, resulting, for example and in particular under extreme thermal conditions, only in carbonization of the plastics material.

Furthermore, the plastics material and/or the polymer structure of the plastics material can be designed such that it is at least partially biodegradable. This means that the component body can be designed sustainably and in a resource-saving manner.

In addition, it is possible for a flame retardant for a plastics material arranged underneath to be formed on the outer layer of the component body, wherein the outer layer can be formed by a coating of the component body. This has the advantage that the outer layer can also be applied after shaping and, furthermore, the type and extent of the coating can determine the flame retardancy or flame retardant. This makes it possible to adapt a component body in accordance with the requirements; this can also be implemented subsequently for existing component bodies.

The coating can be formed by a plastics material which is formed by a polymer structure of the plastics material and/or by an additive which is incorporated in the polymer structure of the plastics material and which substitutes for the perfluorinated or polyfluorinated alkyl compounds (PFAS). The coating can be formed, for example and in particular, by an aforementioned plastics material with a flame retardant. The flame retardant can therefore be formed, for example and in particular, by a polymer structure of the plastics material or by a PFAS-substituting additive which is incorporated in the polymer structure, as described here with reference to the plastic or plastics material containing a flame retardant. The features described above can therefore be transferred analogously to a plastic or plastics material for the coating. The invention takes into account that the coating can also be configured and designed for the application of a marking. The coating can be either opaque or transparent. Furthermore, the coating in a transparent embodiment can be configured and designed according to the invention such that a marking can be applied to an underlying layer, for example and in particular by means of laser irradiation/laser marking.

The requirements for a component body of a connection component can be very high. In order to meet these requirements, it is advantageously provided that the flame retardant can be configured and designed at least for flame retardancy of the plastics material of flame retardancy class V2, in particular V1, preferably V0 or preferably HB (Horizontal Burning), according to UL 94. The values determined according to UL 94 are based on an established classification method for plastics materials by Underwriters Laboratories (UL). This provides a reproducible method for assessing and classifying the flammability of plastics materials. The relevant provisions are mirrored, with the same content, in the IEC/DIN EN 60695 Nov. 10 and −20 standards and the Canadian standard CAN/CSA C 22.2 No.017 in the currently valid version. The invention can thus succeed in providing a component body with reproducible or testable properties that can be classified accordingly.

The embodiment of the component body can be carried out in a variety of ways within the scope of the invention. In particular, the component body can be a housing part or a frame part or an insert in which at least one contact element is inserted and/or through which at least one cable can be passed.

In particular, such a component body can be a fixed-pole or modular contact insert, in which one or more contact elements can be arranged in a housing part. The at least one contact element can have a spring force connection mechanism, a screw connection mechanism, a crimp connection mechanism, etc. Contact inserts can allow for the transmission of data, signals and power. The contact inserts can be inserted into a sleeve housing, which can be made of plastics material or metal, and can be secured there by a latching or screwing mechanism. The contact inserts can be made of the following plastics material or polymer materials, for example:
polycarbonate (PC)
polyamide (PA)
polyketone (PK)
polybutylene terephthalate (PBT),
and contain any kind of reinforcing materials. The contact inserts are usually laser-markable and contain flame retardant additives, as long as there is no inherent flame retardancy.

The component body can also be a frame part. This frame part can, for example, be a module frame for accommodating contact inserts. Furthermore, the frame part can be a cable feedthrough frame through which at least one cable can be passed.

The connection component can be a plug connector component. Furthermore, it is also possible that the connection component can be a connection terminal, such as a series terminal that can be snapped onto a mounting rail or busbar, or a printed circuit board connection terminal.

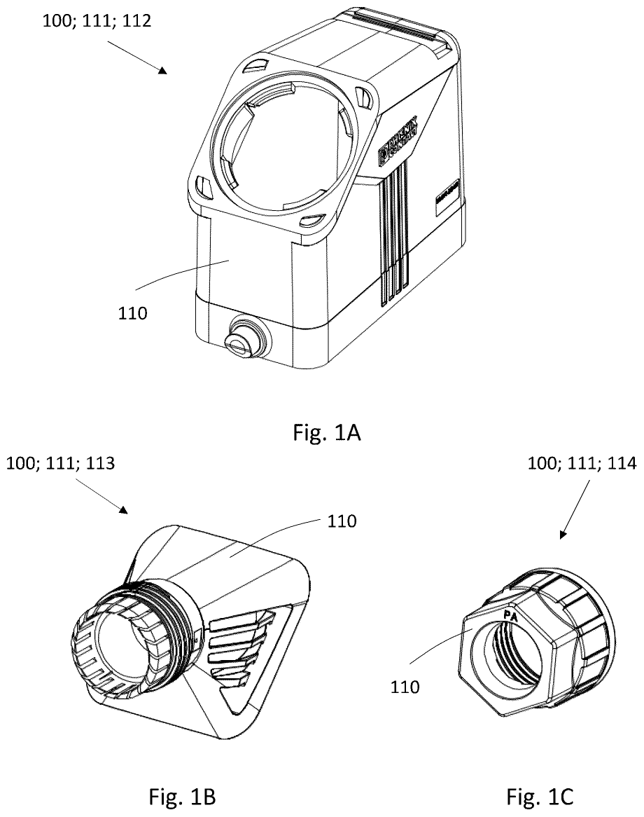

In FIGS. 1A to 5B shown here, various types of component bodies 100 of a connection component, in particular of a connection component designed as a plug-in connector part, are shown by way of example, wherein all of these component bodies 100 are formed in portions from a plastics material 110, wherein the plastics material 110 comprises a flame retardant. The plastics material 110 can comprise, for example, polycarbonate (PC) or polybutylene terephthalate (PBT) or polyamide (PA), polyketones (PK) or polybutylene terephthalate (PBT) or polymer blends such as polycarbonate (PC) with acrylonitrile-butadiene-styrene copolymer (ABS) or polycarbonate (PC) with polyethylene terephthalate (PET) or polycarbonate (PC) with polybutylene terephthalate (PBT). The plastics material 110 is free of perfluorinated or polyfluorinated alkyl compounds (PFAS) and the flame retardant is formed by a polymer structure of the plastics material 110 and/or by an additive which is incorporated in the polymer structure of the plastics material 110 and which substitutes for the perfluorinated or polyfluorinated alkyl compound (PFAS), and/or by an outer layer formed on the component body 100.

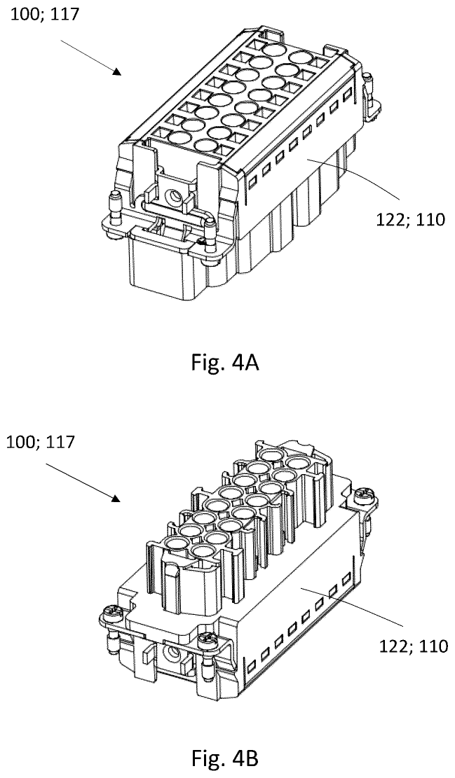

FIGS. 1A to 1C are the component body 100 in the form of a housing part 111, which has a base body 112, a cable outlet grommet 113 and a union nut 114. The base body 112, cable outlet grommet 113 and union nut 114 can each be made of the PFAS-free plastics material 110 according to the invention, which has the corresponding flame retardant. The housing part 111 in this case is a sleeve housing in which at least one contact element, as well as contact inserts 116, 117 as shown in FIG. 3A to 3D and FIGS. 4A, 4B, can be inserted. The cable outlet grommet 113 can be arranged on the base body 112 via a bayonet lock and by screwing the union nut 114 onto the cable outlet grommet 113. A cable passed through the cable outlet grommet 113 can be clamped in order to form a strain relief for the connected cable.

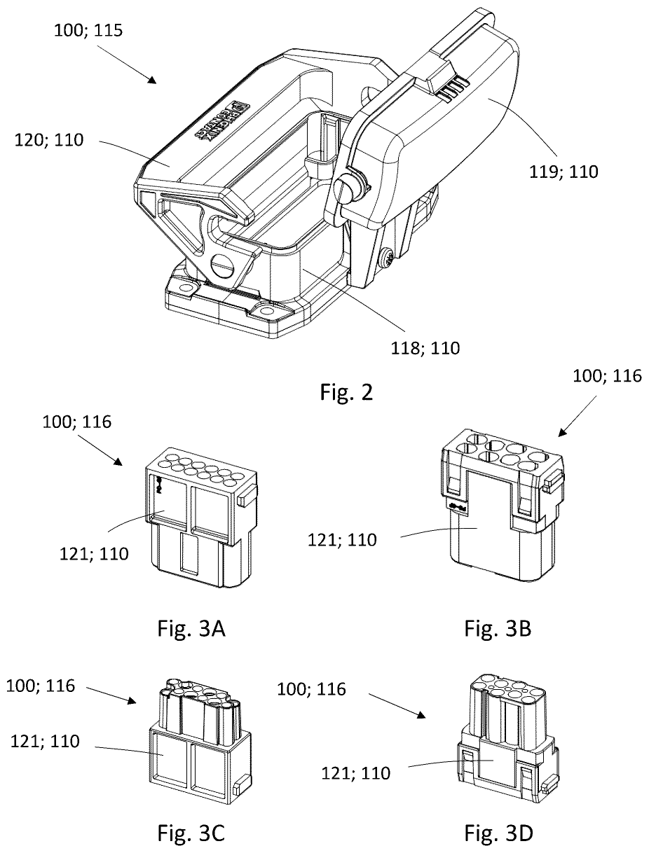

FIG. 2 shows the component body 100 in the form of a frame part 115. Modular contact inserts 116, as shown in FIGS. 3A to 3D, or fixed-pole contact inserts 117, as shown in FIGS. 4A, 4B, can be inserted and held in the frame part 115. The frame part 115 shown here has a base body 118, a cover 119 arranged on the base body 118 and a retaining bracket 120. All parts of the frame part 115, i.e., base body 118, cover 119 and retaining bracket 120, can be made of the PFAS-free plastics material 110 according to the invention, which has the corresponding flame retardant.

The modular contact inserts 116 shown in FIGS. 3A to 3D also represent component bodies 100 for a connection component, each of which has a housing part 121 in which multiple contact elements are inserted. Here, too, the housing parts 121 are made of a corresponding PFAS-free plastics material 110 with flame retardant.

The fixed-pole contact inserts 117 shown in FIG. 4A and 4B also represent component bodies 100 for a connection component, each of which has a housing part 122 in which multiple contact elements are inserted. Here, too, the housing parts 122 are made of a corresponding PFAS-free plastics material 110 with flame retardant.

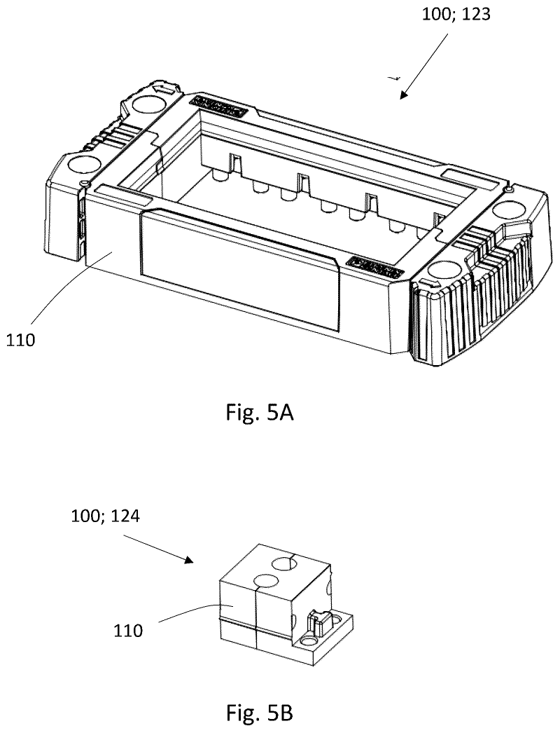

FIG. 5A is a component body 100 as a frame part 123, which is made of a corresponding plastics material 110 with flame retardant. Multiple component bodies 100 as shown in FIG. 5B can be inserted in the frame part 123; these are inserts 124 made of a corresponding PFAS-free plastics material 110 through which cables can be passed. The frame part 123 thus forms a cable feedthrough frame. Both the frame part 123 and the inserts 124 arranged therein are thus made of a corresponding PFAS-free plastics material 110 with flame retardant.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

100 Component body
110 Plastics material
111 Housing part
112 Base body
113 Cable outlet grommet
114 Union nut
115 Frame part
116 Modular contact insert
117 Fixed-pole contact insert
118 Base body
119 Cover
120 Retaining bracket
121 Housing part
122 Housing part
123 Frame part
124 Insert

1. A connection component for an electrical conductor, comprising:
at least one component body comprising, at least in portions, a plastics material,
wherein the plastics material comprises a flame retardant,
wherein the plastics material is free of perfluorinated or polyfluorinated alkyl compounds, and
wherein the flame retardant comprises a polymer structure of the plastics material and/or an additive incorporated in the polymer structure of the plastics material that substitutes for the perfluorinated or polyfluorinated alkyl compounds, and/or an outer layer formed on the component body.

2. The connection component of claim 1, wherein the plastics material and/or the polymer structure of the plastics material is adapted such that heating above a melting temperature of the plastics material causes flame-free melting of the plastics material.

3. The connection component of claim 1, wherein the plastics material and/or the polymer structure of the plastics material is adapted such that a flame-free drop formation of the plastics material occurs at a heating temperature at or above a melting temperature of the plastics material so as to melt the plastics material, forming droplets.

4. The connection component of claim 1, wherein the additive comprises a filler.

5. The connection component of claim 1, wherein the additive comprises an inorganic substance.

6. The connection component of claim 5, wherein the inorganic substance comprises a phosphorus substance and/or a nitrogen substance and/or a bromine substance.

7. The connection component of claim 1, wherein the plastics material and/or the polymer structure of the plastics material comprise at least one of the following polymers:
polyetherketone,
high-temperature-resistant plastics material comprising polyphenylene sulfide,
synthetic polymer comprising silicones,
polyethylene comprising high molecular weight polyethylene,
polycarbonate,
polyamide,
polyketones,
polybutylene terephthalate,
polymer blends comprising polycarbonate with acrylonitrile-butadiene-styrene copolymer, or polycarbonate with polyethylene terephthalate, or polycarbonate with polybutylene terephthalate.

8. The connection component of claim 1, wherein the plastics material and/or the polymer structure of the plastics material comprise an organic compound structure and/or inorganic compound structure at least in portions.

9. The connection component of claim 8, wherein the inorganic compound structure comprises phosphorus and/or nitrogen.

10. The connection component of claim 1, wherein the plastics material and/or the polymer structure of the plastics material is adaptedsuch that the flame retardant is formed by a crosslinking modification by gamma and/or beta irradiation.

11. The connection component of claim 1, wherein the plastics material and/or the polymer structure of the plastics material is adapted so as to be at least partially biodegradable.

12. The connection component of claim 1, wherein a flame retardant for the plastics material arranged underneath is formed on an outer layer of the component body, and
wherein the outer layer comprising a coating of the component body.

13. The connection component of claim 12, wherein the coating comprises a plastics material formed by a polymer structure of the plastics material and/or by an additive incorporated in the polymer structure of the plastics material that substitutes for the perfluorinated or polyfluorinated alkyl compounds.

14. The connection component of claim 1, wherein the flame retardant is adaptedat least for flame retardancy of the plastics material in flame retardancy class V2 of UL 94.

15. The connection component of claim 1, wherein the component body comprises a housing part or a frame part or an insert in which at least one contact element is inserted and/or through which at least one cable is passable.

16. The connection component of claim 10, wherein the gamma and/or beta irradiation comprises X-ray irradiation.

17. The connection component of claim 14, wherein the flame retardant is adapted at least for flame retardancy of the plastics material in flame retardancy class V1 of UL 94.

18. The connection component of claim 14, wherein the flame retardant is adapted at least for flame retardancy of the plastics material in flame retardancy class V0 of UL 94.

19. The connection component of, wherein the flame retardant is adapted at least for flame retardancy of the plastics material in flame retardancy class HB, of UL 94
